(19) United States
(12) Patent Application Publication
(10) Pub. No.: US 2008/0029774 A1
(43) Pub. Date: Feb. 7, 2008

(54) Semiconductor light source packages with broadband and angular uniformity support

(75) Inventors: Alexander Valerievich Shishov, Moscow (RU); Yevgueni Tofik Aliyev, Moscow (RU)

Correspondence Address: ACOL TECHNOLOGIES S.A., P.O. BOX 757, LA JOLLA, CA, 92038, US

(73) Assignee: ACOL Technologies S.A.

(21) Appl. No.: 11/499,082

(22) Filed: Aug. 4, 2006

(51) Int. Cl. H01L 33/00

(52) U.S. Cl. 257/96

(57) ABSTRACT

Optical sources presented are comprised of a semiconductor emitter and supporting package system including a hard plastic lens cover and mounting substrate with electrical and mechanical support for the semiconductor. A cavity is formed between the lens cover and substrate which supports addition of materials which cooperate with optical propagation and produce some interaction or effect with respect to the beam. Some versions include dispersants and wavelength shifting materials. In any case, the arrangement and spatial distribution of these materials is not trivial. Both the cavity shape and material placement effect the final output of systems produced here. Well designed filling ports in the substrate permit injection of viscous material such that some preferred spatial distribution is realized. Filling port position may cooperate with separate cavities or may merely encourage natural distribution dictated by flow properties of the materials.

### BACKGROUND OF THESE INVENTIONS

1. Field

The following inventions disclosure is generally concerned with semiconductor light sources and specifically concerned with light source package construction and arrangement to effect preferred optical outputs regarding spectral and beam uniformity characteristics.

2. Prior Art

Some light emitting diode LED designs include systems having a semiconductor die immersed in a resin which forms a lens with an air interface. In other designs, light from the die first enters a cavity of air, then enters a transparent plastic (resin/polymer) body formed as a lens having a spherical surface. In advanced designs, the cavity described above may be filled with certain compounds which permit light transmission and sometimes additionally impart some action/effect on light passing therethrough. No matter the precise nature of these designs, it is always a material issue to consider optical matching between these components for best control of output characteristics.

A few examples of related teachings include: US applications numbered: US2003/0211804A1; US2002/0185966A1; and US2003/0067264A1. In addition PCT publication W003/010832A1; and European patent EP 1187226A1 similarly disclose concepts relating to optical cooperation between elements of LED packages.

One difficulty which accompanies many LED package designs relates to angular uniformity. The optical output from semiconductor sources is typically brightest on the symmetry axis and reduced at all angles therefrom. However, the angular dependence of brightness is non-Lambertian. Sometimes, the brightness level does not fall off in a smooth way, but rather includes bright and dark loci in a plot of various brightness curves as a function of angle. Sometimes, artisans have applied various dispersant mechanisms including adding ground glass to LED packages to more closely approximate a Lambertian emitter. Some examples of these systems are described in documents as follows:

U.S. Pat. No. 3,875,456 of Apr. 1, 1975; U.S. Pat. No. 4,152,624, May 1, 1979; and U.S. Pat. No. 6,653,765, Nov. 25, 2003. Of special interest, Japanese patent numbered JP 2005064233, dated Mar. 10, 2005—silicon dioxide, aluminum oxide, barium sulfate, calcium carbonate, barium oxide, and titanium oxide dispersants are mixed with a binder material of epoxy resin to provide a dispersing effect on light emitted from a semiconductor emitter.

In conventional LEDs which include combinations of dispersants and phosphors, epoxy resins are used as a binder material. At high concentrations of mechanical dispersant, these resin based binding materials becomes difficult to work and manipulate. In addition, producing mechanical dispersants suitable for use with resin is rather complex technological process demanding formation of particles with appropriate and regular size, shape and refractive index. The art is troubled by ineffective dispersant systems and alternatives are widely sought.

While systems and inventions of the art are designed to achieve particular goals and objectives, some of those being no less than remarkable, these inventions have limitations which prevent their use in new ways now possible. Inventions of the art are not used and cannot be used to realize the advantages and objectives of the inventions taught herefollowing.

### SUMMARY OF THESE INVENTIONS

Comes now, Aliyev, Y. T. and Shishov, A. V. with inventions of optical sources including packages arranged to provide bandwidth and uniformity improvements in optical outputs. It is a primary function of these optical systems to provide optical beams having high angular uniformity and broadband or ‘white’ light output. Particularly, these packages are arranged in special, easy-to-manufacture arrangements which permit inexpensive construction which cooperates with manual and automated fabrication processing.

Special filling ports provide access to holding cavities. Various important materials such as colloids of phosphors and dispersants may be injected through these filling ports to impart a desired distribution of material which promotes a beneficial optical effect. Dispersants and phosphors may be appropriately distributed in a predetermined spatial manner such that their interaction with an optical beam produced at a semiconductor will be effected in a desirable way. Light produced in and leaving a semiconductor chip in a known spatial pattern (set by the surface conditions of the solid forming the device—as well as the connector geometries) passes through these colloid materials. As distribution of the colloid materials includes consideration of semiconductor chip emission properties, interaction with the materials is ‘tuned’ to impart a desired end result. Such results include improving angular distribution by controlled scattering and forming broadband output by conversion of output wavelengths via wavelength shifting phosphors. Specifically, a new approach for light scattering media compositions in the LEDs is proposed. These include small air bubbles, and small oil drops in binder material or a mixture of air bubbles and oil drops with other mechanical dispersant.

### OBJECTIVES OF THESE INVENTIONS

It is a primary object of these inventions to provide advanced semiconductor light source packages.

It is an object of these inventions to provide semiconductor light source packages which support broadband and spatial uniformity.

It is a further object to provide semiconductor light source packages which combine phosphors and mechanical dispersants.

It is an object of these inventions to provide new arrangements of diode light emitter mechanical packages which incorporate facility and means to support advanced uses of dispersants in connection with wavelength shifting phosphors.

A better understanding can be had with reference to detailed description of preferred embodiments and with reference to appended drawings. Embodiments presented are particular ways to realize these inventions and are not inclusive of all ways possible. Therefore, there may exist embodiments that do not deviate from the spirit and scope of this disclosure as set forth by appended claims, but do not appear here as specific examples. It will be appreciated that a great plurality of alternative versions are possible.

### BRIEF DESCRIPTION OF THE DRAWING FIGURES

These and other features, aspects, and advantages of the present invention will become better understood with regard to the following description, appended claims and drawings where:

FIG. 1 is a cross section diagram of a special optical package of these systems;

FIG. 2 illustrates injection of a special material into a cavity of prescribed shape;

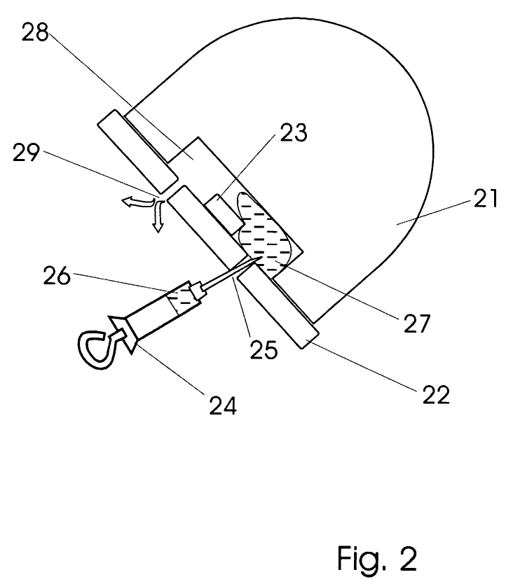

FIG. 3 is another section diagram of an alternative version;

FIG. 4 is a section diagram of an important compound version;

FIG. 5 illustrates a special mechanical auxiliary system;

FIG. 6 shows an alternative injection scheme;

FIG. 7 illustrates a special colloid medium of phosphor grains combined with a dispersant agent (air bubbles); and

FIG. 8 is a sectional drawing of a special package version.

### GLOSSARY OF SPECIAL TERMS

Throughout this disclosure, reference is made to some terms which may or may not be exactly defined in popular dictionaries as they are defined here. To provide a more precise disclosure, the following terms are presented with a view to clarity so that the true breadth and scope may be more readily appreciated. Although every attempt is made to be precise and thorough, it is a necessary condition that not all meanings associated with each term can be completely set forth. Accordingly, each term is intended to also include its common meaning which may be derived from general usage within the pertinent arts or by dictionary meaning. Where the presented definition is in conflict with a dictionary or arts definition, one must use the context of use and liberal discretion to arrive at an intended meaning. One will be well advised to error on the side of attaching broader meanings to terms used in order to fully appreciate the depth of the teaching and to understand all the intended variations.

### Optically Cooperative Material

Herein throughout this disclosure, we use the term ‘optically cooperative material’ meaning optical media which interacts with light passing therethrough. Generally at least partly transparent, these media are sometimes and preferably arranged as a suspension of matter in a binder agent. The materials cooperate with and promote optical conduction while at the same time imparting some influence on beams passing therethrough.

### Dispersant

A dispersant is any physical body which operates on incident light to cause a change in its propagation direction. This may be via reflection, refraction, diffraction or any combination of these.

### Wavelength Shifting Media

A wavelength shifting medium is a material which operates on incident light to produce a change in its wavelength. Generally a phosphor absorbs light of a high energy and re-emits light at a lower energy—i.e. the process is lossy.

### Mounting Pad

The term ‘mounting pad’ may merely refer to a position on a substrate to which a semiconductor may be affixed. It may also include a mechanical bonding agent and electrical support such as electrical contacts. However, a mounting pad primarily refers to the location to which a semiconductor belongs.

### PREFERRED EMBODIMENTS OF THESE INVENTIONS

In accordance with each of preferred embodiments of these inventions, there is provided semiconductor optical sources having output with a high degree of angular uniformity. It will be appreciated that each of embodiments described include apparatus and the apparatus of one preferred embodiment may be different than the apparatus of another embodiment.

Typical semiconductor light sources are generally referred to as ‘LED’s or light emitting diodes. While special cases include semiconductor lasers, in general we consider diode source whether or not stimulated emission is included. When considering these sources, one may refer to them as an ‘LED’. However the name seems to only include the diode but not the supporting package in contrast to its common use. By ‘LED’, it is meant in the arts that the semiconductor chip, its electrical supports and mechanical supports are included. Thus, LED includes the diode semiconductor and the supporting package and systems.

Special LED packages and those included here are comprised primarily of two major elements including a lens cover and a substrate. A substrate is used to mechanically and electrically couple a semiconductor die or ‘chip’ in a fashion whereby it operates to produce light when energized. A lens cover is included to provide optical coupling from the semiconductor chip, or plurality of chips, into an output beam. In addition to these two important elements, certain LED packages designed with particular performance properties in mind may also include such elements as phosphors which operate to change the system wavelength and dispersants to spread light into an optical beam having good angular uniformity. Phosphors can be used to change a portion of high energy photons into lower energy photons of longer wavelengths. In this way, one can arrive at a system with broadband outputs. Further, dispersants can be used to cause highest intensity light on axis to be coupled into off axis directions thereby evening the intensity for various small angles. Thus, it can be said that some high performance LED systems are comprised of a semiconductor die (at least one), a substrate, a lens cover, phosphors and dispersants. It is implied that these are accompanied by electrical and mechanical support systems as well.

It is an important aspect of these inventions that these lens covers and substrates cooperate together and jointly form an enclosed cavity. When a lens cover is pushed to and joined with a substrate via any of various coupling means, an enclosed space remains between them. This space is intentionally formed to accommodate the semiconductor die, its mechanical and electrical couplings, phosphor wavelength shifting media and dispersants. The size and shape of such cavities are carefully designed with a view to supporting a particular optical output.

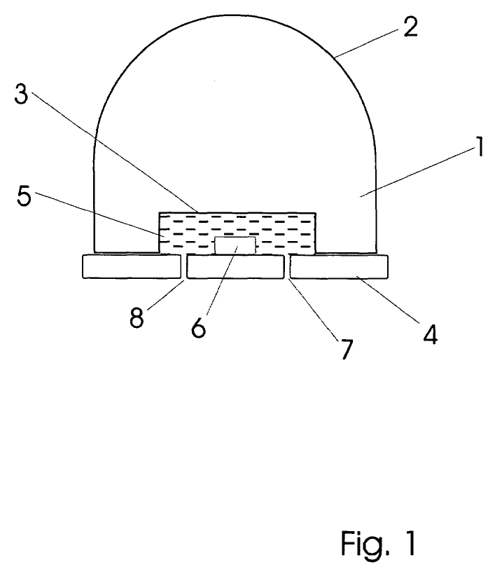

A first version of these inventions may be understood in view of the diagram of FIG. 1. A lens cover 1 may be made of a hard optical plastic formed in a molding process. These may be made from polymer materials which are durable and inexpensive. As the device shape depends only upon the mold shape, complex shapes having many curved sections are readily made. This is important because in these inventions it is desirable to have an undersurface of prescribed shape. The lens thus has a top surface 2 in some versions in the shape of a substantially spherical section which operates to concentrate light in the normal lensing action. The lens cover additionally has an undersurface 3 which, in conjunction with substrate 4, forms a cylindrically shaped cavity 5. The reader is reminded that the figure is meant to show a cross section in a plane which contains the symmetry axis. Thus, while the cavity is shown in rectangular representation, it is easily understood that the shape is in fact a rotation of a rectangle which forms a cylinder.

The cavity may be filled with an optically active or ‘optically cooperative’ material. An optically active material might be one which emits light such as a photophosphor type material. In contrast, an ‘optically cooperative’ material might be one which is not necessarily optically active but still operates to interact with optical beams propagating therethrough.

The optically cooperative material or materials may be injected into the cavity such that it comes into close proximity or entirely covers and surrounds a semiconductor die 6. In preferred versions, optically active material is injected to completely fill the cavity. In this way, good thermal conduction provides a heat escape path from the semiconductor to both the lens cover and substrate to improve cooling characteristics of the system. In addition, well placed material in accordance with this description also assures good optical homogeneity.

The optically cooperative material(s) may be injected into the cavity after the lens cover and substrate are brought together and joined to form the enclosed cavity. These optically cooperative materials may be injected through filling ports 7 and 8. One or more fill ports may be provided as needed in various important locations on the substrate. Either of these ports might also operate an ‘exhaust’ or ‘exit’ port as well. When material is being injected via a first port, the other port permits air and excess material to escape.

In review, it is important to note that a substrate having ports therein is joined with a lens cover to form an enclosed cavity of prescribed shape. The molded shape of the under surface of the lens cover provides definition as to the cavity shape and size.

To more fully appreciate details of these inventions, figure two is provided to illustrate injection of an optically cooperative material in a viscous form. Lens cover 21 includes a shaped undersurface which provides an enclosed cavity when the lens cover is joined with and coupled to substrate 22. A semiconductor light emitting device 23 is affixed to the substrate and mechanically and electrically coupled therewith. An injection tool 24, or simple syringe, permits a fine needle 25 to address the filling port whereby viscous material 26 may be pushed from inside the injection tool into the cavity. As the optically cooperative material 27 enters the enclosed cavity and begins to fill it including taking up the precise shape of the cavity, it also pushes air 28 such that the air and any excess material exits the cavity at port 29.

It is meaningful to note that since the viscous optically cooperative material takes up the shape of the cavity precisely, the spatial distribution of the optical material of a final device is dictated by the shape of the cavity and more precisely the undersurface of the lens cover. Thus, since one can effect the spatial distribution of optically cooperative material via the design of the undersurface of the lens cover, this design ultimately effects that beam shape and characteristics. For example, if the optical material is a dispersant material, then more or less dispersant can be applied to various angles with respect to the system axis and thus permit a controlled application of dispersant and result in a beam having ideal divergence characteristics.

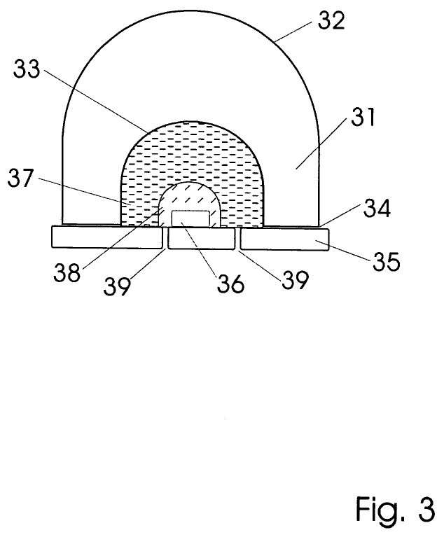

Some preferred embodiments include a simple configuration where light emitted from a semiconductor diode passes through a first optically cooperative material, and then thereafter in the optical train, passes through a second optically cooperative material. The first optical material may be delivered and provided to envelope and cover the semiconductor. The second optical material may be provided to envelope the combination of the semiconductor and first optical material to effect a ‘nested’ system of elements. Light emitted from the semiconductor necessarily passes through the first optically cooperative material and interacts therewith. After, the light passes from the first optical material and into the second. As it further passes through the second optically active material it is subject to further interaction therewith that material which may be different than the first. That is to say the optical effect imparted to the beam may be different to the effect provided by the first. In this way, the system may be characterized as multi-layered where each layer is comprised of a different composition. One of such configurations is illustrated in the drawing presented here as FIG. 3.

A lens cover 31 is formed of hard plastic or polymer material in a molding process which imparts a lensing type smooth top surface 32 and an undersurface 33 which may have particular shape such as spherical or other desired configuration. It is of considerable importance that the undersurface form a partially enclosed cavity space; or a region characterized as ‘concave’. It is not necessary that the surface be rectilinear or spherical; but rather it may in fact be a compound and complex system of curves joined together to form a concavity without natural geometric description. The lens cover also includes a seating surface 34 which permits it to be joined to and coupled with substrate 35 which may be substantially flat.

In preferred versions, the substrate top surface is smooth and flat and is joined to a cooperating seat similarly smooth and flat. However, in other versions it is anticipated that cooperating mechanical interlock surfaces might operate to join these elements together. In either case, when a lens cover element and a substrate are joined together, a substantially enclosed cavity is formed therebetween. The space is suitable for receiving therein one or more semiconductor elements and optically cooperative materials. In particular, a light emitting diode 36 may be mounted and electrically coupled to the substrate at a semiconductor mounting pad fashioned at the top surface of the substrate.

A mounting pad may provide electrical and/or mechanical support and coupling between a substrate and a semiconductor chip. However for purposes of this disclosure, a mounting pad may be merely a location on the substrate without any particular specification as to electrical or mechanical mounting. A mounting pad suggests the place where a semiconductor die may be joined to a substrate. This is important because the location of filling ports in relation to those mounting pads can dictate the final position and distribution of injected optical materials.

In addition, an optical material such as a wavelength shifting material 37 including phosphor, or an optical material such as a colloid 38 comprising a dispersant agent may fill the cavity space. Combinations of these are fully anticipated and are the subject of some preferred embodiments. Fill ports 39 may be suitably located in the substrate whereby fluid materials injected therethrough form shaped volumes of optical materials inside the cavity space. In one example, a first material is injected through the fill port close to the semiconductor or mounting pad. That material may form an envelope about the semiconductor and completely surround it. It may thereafter cure to a state where it is stable and tends not to move with regard to position or shape. A second fill port may be used to inject a different optically cooperative material. Similarly, this material may cure to form a hardened element of desired shape and location. In this way, light emitted by the semiconductor is subject to passing through both types of optically cooperative material before leaving the device through the lens cover top surface. The optical output of the system is improved because wavelengths emitted may be broadband and the beam shape including angular divergence and uniformity may be controlled to desired states. Thus, these systems anticipate multi-layer and multi-composition configurations.

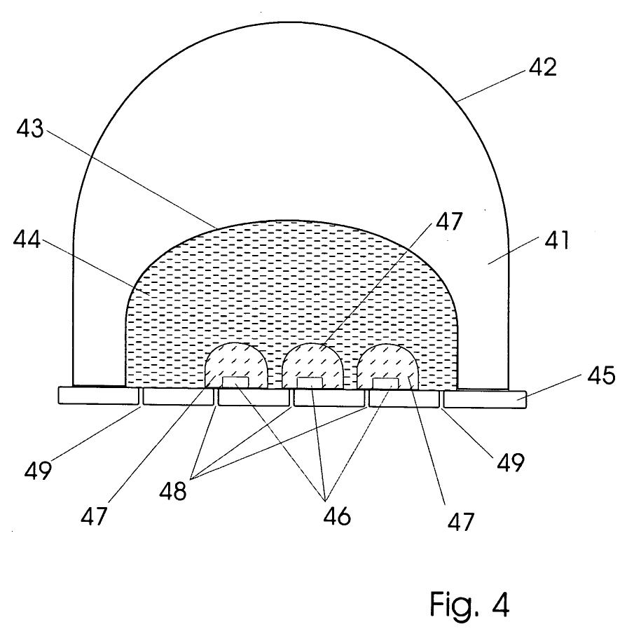

FIG. 4 shows a special version of these systems which accommodates a plurality of semiconductor dice, each with its own and separate mounting location and associated optically cooperative material. Further and simultaneously, the system includes another optically cooperative material which is shared by all semiconductor devices. The device is realized as follows. A substrate is prepared with a plurality of mounting pads, one each for each semiconductor of the system design. In addition, the substrate is prepared with a plurality of filling ports. There may be a one-to-one correspondence between some filling ports and mounting pads. Semiconductor die are mounted one each at every mounting pad such that the substrate supports these dice mechanically and electrically. Thereafter, a lens cover having a specially shaped undersurface is pressed to and joined with the substrate to form a cavity therebetween. Optically cooperative materials are injected into the cavity space via the various fill ports. These materials may differ in their characteristics. For example, each may contain a different phosphor which has an emission wavelength in a different part of the spectrum than the others. In this way, it is possible to realize a broadband output from a plurality of chips and phosphors of different color. The ensemble of light outputs can be thereafter (in the optical train) subject to a common dispersion system. Optical material contained in the remaining portions of the cavity may be used to impart dispersion action on light passing therethrough.

It is easy to appreciate configurations possible when considering the diagram of FIG. 4 where an example of such system is illustrated in detail. Particularly, a lens cover 41 with top surface 42 and undersurface 43 forms a cavity 44 as it is coupled and connected to substrate 45. The substrate has three semiconductor die 46 affixed at a plurality of mounting pads distributed about the substrate surface such that there is sufficient spacing between each with respect to the other. Space is allotted such that each chip may be covered by an orb of optically cooperative material 47. These materials may be injected at the various fill ports 48, one each associated with each mounting pad of the substrate. The system may further include additional fill ports or exhaust ports 49 not associated with any semiconductor mounting pad. These ports support adding material to fill the entire cavity and cover the individual blobs of material over each chip.

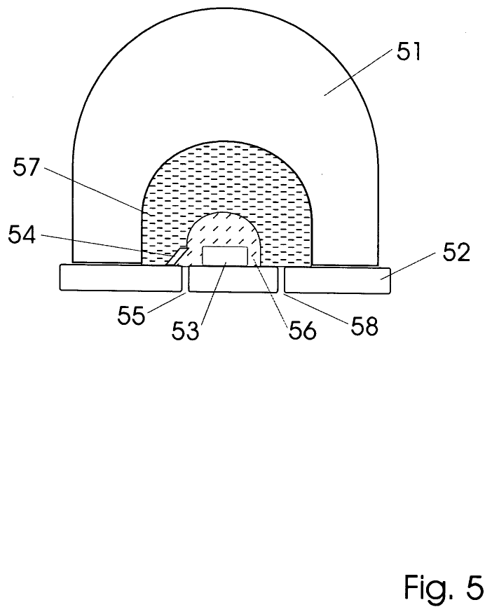

In certain versions, it is desirable to include as part of the package a special provision which aids in assembly. It has no material effect on the optical operation of the device after it is fully assembled and operational; however during assembly, it aids to position and form a portion of the optically cooperative material. Specifically, it deflects material injected at a certain fill port toward a preferred position/location. It is desirable to cover and completely surround a semiconductor die with material such that it forms an envelope thereabout. Since a fill port must be displaced from the chip and its mounting pad at the substrate, it is preferred to direct injected material so that it migrates away from the fill port and toward the semiconductor geometric center or sometimes the system axis. This is more easily understood in view of the drawing of FIG. 5. A lens cover 51 is joined with a substrate 52. The substrate, having a mounting pad thereon, supports electrical and mechanical connections with a semiconductor die 53, for example a light emitting diode. The substrate may additionally be prepared with a deflection element 54 which is devised and positioned in conjunction with fill port 55. Optically cooperative material 56, for example a wavelength shifting material such as phosphor, which is injected into the cavity at fill port 55 is pushed to the right (in the figure) and over the semiconductor die to form an orb 56 of material which covers and surrounds the die. Any light emitted therefrom necessarily passes through the material and is forced to interact therewith in accordance with its design characteristics. Additional optically cooperative materials 57 may also be injected through a second fill port 58 to completely fill the balance of space in the cavity formed by the combination of the lens cover and the substrate. For example a dispersant material can be injected to completely surround and envelope a wavelength shifting material (56) and semiconductor die 53. In this way, it also causes light emitted by the semiconductor to interact with that material.

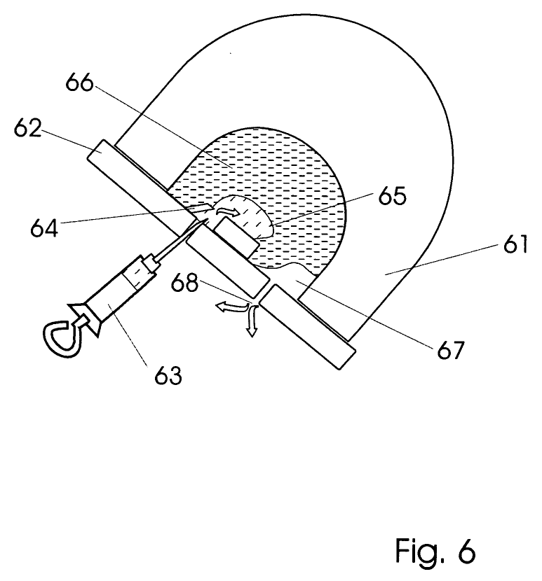

Special preferred versions are illustrated in FIG. 6. Namely, versions where a first material is put into an enclosed cavity, and thereafter a second material is injected. Later injection of the second material tends to displace reposition the earlier injected first material. In a manufacturing process, a lens cover is joined with a substrate to form an enclosed cavity. An optically cooperative material in a viscous state is introduced into the cavity space. Thereafter, a second distinct optically cooperative material is injected such that the first material tends to be pushed aside. This is more understandable in view of the drawing. Lens cover 61 having an undersurface including a spherical section is pushed and affixed to a substrate 62 having a substantially flat top surface. An injection tool 63 containing a viscous optically cooperative material in inserted into a filling port whereby material may be transferred from the tool to the cavity. For illustrative purposes, the tool is shown as a syringe; however, one will appreciate that highly automated machinery arranged for mass production might have specialized tools of alternative configurations. A deflection element 64 tends to cause injected materials 65 to be deflected towards and over the semiconductor element affixed to the substrate at the mounting pad. The second material type 65 may push aside another material type 66 injected in a previous step. Air 67 and any excess material in the cavity tends to escape via exhaust port 68. In this way, one can produce a compound system having a semiconductor emission output modified by two or more different optically cooperative materials having an advantageous spatial distribution within a cavity formed between a lens cover element and substrate. Accordingly, a multilayered optical system of various optical materials may be created.

The term ‘dispersant bodies’ is chosen with care as many different type of physical bodies/structures can serve well to disperse light. Further, various forms of these bodies may be particularly well suited for integration with some of systems taught herein. Dispersant bodies may be either from the group including: crystalline structures, granular matter, inhomogeneous matter, and air bubbles or oil drops for example. It is noted that use of air bubbles and oil drops instead of mechanical dispersant is a good possibility. These could be injected or generated in binding materials by application of ultrasonic energy. It is possible to regulate by frequency and intensity of ultrasonic energy the concentration and size of air or oil beads. In this way, one may adjust appropriate size and concentration of air and oil beads for effective scattering of emitting light. High concentration of air or oil beads doesn't appreciably influence the viscosity of binder material. It is also possible to vary the refractive index of oil beads by using of different oils and correspondingly to vary the average refractive index for the mixture of air and oil beads. In preferred versions, the sizes of beads are of the order of light scattering wavelength; for UV/blue chips λ˜0.3÷0.5 μm. Preferably the mean particle sizes are less than about 5 μm and more than about 0.03 μm.

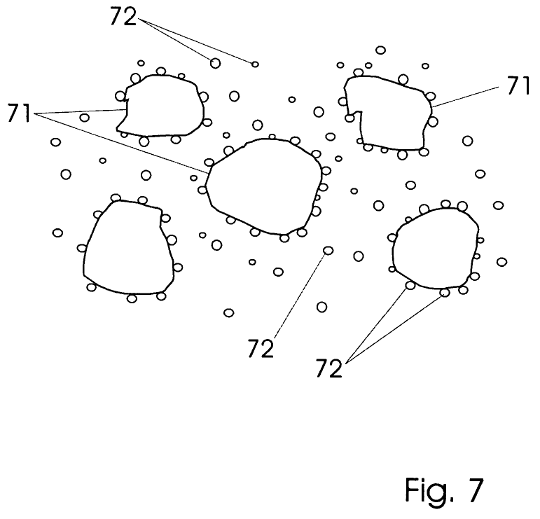

FIG. 7 illustrates an important concept of these inventions. In one preferred system, air bubbles are formed and affixed (if merely by surface tension) to grains of phosphor. Thus in these special versions, both the wavelength shifting medium and the dispersant are tightly integrated. In this special case, a preferred semiconductor light emitter package would be best represented as that embodiment shown in FIG. 1. The volume is not separated into two portions, but rather the optically cooperative material including both wavelength shifting and dispersing function are mixed together and occupy the identical volume uniformly, a cavity formed between a cover lens and the substrate.

In general, the bigger the phosphor grains are, the higher will be the resulting wavelength conversion efficiency (see Patent Application US20050035365 A, Dec. 10, 2005). However, for big phosphor grains (more than 10 μm) there is a problem related with active precipitation (deposition) of the grains in the binder materials that makes worse the optical quality of the system. When using air bubbles as dispersant, air bubbles will partially cover the surface of phosphor grains and provide a ‘floating-up’ effect for big phosphor grains that prevents precipitation in the binder material. At the same time, large free spaces between big phosphor grains prevent phosphor packing and loss emitted light. In preferred versions, these free spaces are filled by air and oil beads or mixture of air and oil beads and other dispersant that provide more effective use of light.

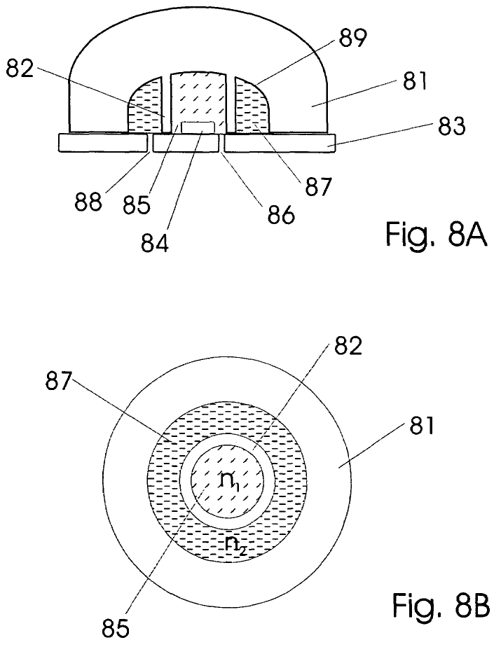

FIG. 8 shows special versions of these inventions. A specially shaped lens cover has an underside with a divider system. When coupled with an appropriate substrate, the lens cover/substrate combination form a compound cavity of two portions. Specifically, a compound cavity is formed having two concentric and axially symmetric portions. A first portion, central and within a second annular portion, forms a substantially cylindrical volume. The second portion is annular and forms a ‘donut’ shaped element which surrounds the first. Each cavity portion may be filled with a different material. For example, the first cavity portion may be filled with a dispersant material—while the second portion is filled with a wavelength shifting material. Alternatively, these two portions may each be filled by a different dispersant material to provide appropriate dispersion of light emitting of the various sections of the semiconductor die. The lens cover is coupled to a substrate to form the cavities therebetween and is further coupled such that filling holes in the substrate line-up and couple one each to each cavity. A more complete understanding is realized in view of FIG. 8A. Lens cover 81 has an undersurface with specially arranged and annularly shaped dividing member 82 which contributes to form two separate cavities. When this lens cover is coupled to substrate 83, the combination accommodates semiconductor chip 84 on the system axis at a semiconductor mounting pad. First cavity portion 85 may be filled via fill port 86 with an optically cooperative material such as a dispersing agent or ‘dispersant’. Second cavity portion 87 may be filled at fill port 88 with another optically cooperative material—in example a phosphor wavelength shifting material. Because it may not be perfectly clear when illustrating an annular element in a cross section drawing, a second drawing 8B is provided to show an orthogonal view. As a lens cover is typically formed in a molding process, it is easy to appreciate that the underside surface of the lens cover can support complex shapes including those which permit formation of a plurality of cavities as described herein. It is also important to note that each of the two cavities may contain optically cooperative materials of different sorts in various regard. For example, it is sometime advantageous to provide a first material having an index of refraction which is different than the index of refraction of a second material. Manipulation of the index of refraction in spatially distributed volumes can be used to further control the beam shape and characteristics. Accordingly, these inventions support greater control of possible output beams as they support changes to the index of refraction in highly unique arrangements.

In most general terms, apparatus of these inventions may precisely be described as including: semiconductor light sources comprising at least one semiconductor light emitter in combination with an opto-mechanical package with a substrate and lens cover element forming therebetween an enclosed cavity filled with optically cooperative material(s) including a dispersant agent. Further, in some versions these semiconductor light sources with optically cooperative materials are arranged as colloids including a binder media and granular matter held therein. Granular matter is distributed and suspended in the binder to prevent migration about the holding medium such that the material density remains constant. These binders may be described as either: gel; epoxy; resin; polymer; the like; and mixtures thereof. These optically cooperative materials include both wavelength shifting media such as an optically pumped phosphor and light dispersant bodies which provide a dispersion action via either diffraction, refraction, or reflection optical mechanisms. In some special version, light dispersant bodies are merely well distributed air bubbles or tiny oil drops; and sometimes these air bubbles are affixed to the surfaces of phosphor grains.

Of significant importance are the packages' filling ports provided in substrates. In addition, a substrate may also include one or more exit ports. Also, deflection element(s) may be integrated with a substrate to better position material in relation to a semiconductor chip and mounting pad to which it is affixed.

It is an important embodiment that these optically cooperative materials includes arrangements of at least two distinct volumes. In some cases, a first volume is arranged as wavelength shifting media and a second volume is arranged as a dispersant agent. The spatial distribution of these being important to the effect they have on light passing therethrough. These combinations of distinct volumes are arranged to fill and occupy the space of cavities formed between the lens cover and the substrate. In certain versions, wavelength shifting media is enclosed by a dispersant agent. Some substrates include a one-to-one correspondence between filling ports and semiconductor mounting pads. Optically cooperative material can be arranged into a plurality of discrete orbs, a ‘blob’ including phosphor, each forming an association with a particular semiconductor light emitter as it completely surrounds and envelops any of the semiconductor light emitters.

In special versions, a lens cover is arranged with an undersurface forming two distinct axially symmetric and concentric cavities, and a cooperating substrate has at least two fill ports, one each associated with and coupled to each of these separate cavities. In these special versions, it is sometimes preferred that the centrally disposed cavity be filled with phosphor, and the peripheral cavity be filled with dispersant.

One will now fully appreciate how packages for light emitting semiconductors may be arranged to include means in support of output beam dispersion and wavelength shifting functionalities. Although present inventions have been described in considerable detail with clear and concise language and with reference to certain preferred versions thereof including best modes anticipated by the inventors, other versions are possible. Therefore, the spirit and scope of the invention should not be limited by the description of the preferred versions contained therein, but rather by the claims appended hereto.

It is claimed:

1) Semiconductor light sources comprising at least one semiconductor light emitter in combination with an opto-mechanical package, the opto-mechanical package characterized as comprising a substrate element having a filling port therein and a lens cover element, the substrate and lens cover forming therebetween a substantially enclosed cavity, said cavity being filled with at least two optically cooperative materials including a dispersant agent to form a multi-layer system.

2) Semiconductor light sources of claim 1, said optically cooperative material including a dispersant agent is a colloid of binder and grains held therein, the grains being distributed and suspended in the binder whereby they do not easily migrate about such that the grain density remains constant over time.

3) Semiconductor light sources of claim 2, said binder is a material characterized as one from the group including: gel; epoxy; resin; polymer; and mixtures thereof.

4) Semiconductor light sources of claim 2, said grains include wavelength shifting media.

5) Semiconductor light sources of claim 4, said wavelength shifting media is an optically pumped phosphor.

6) Semiconductor light sources of claim 2, said grains include light dispersant bodies.

7) Semiconductor light sources of claim 6, said light dispersant bodies provide a dispersion action via either diffraction, refraction, reflection optical mechanisms.

8) Semiconductor light sources of claim 6, said light dispersant bodies are from the group: air bubbles, oil drops, and mechanical dispersants.

9) Semiconductor light sources of claim 8, said air bubbles are affixed to the surface of phosphor grains.

10) Semiconductor light sources of claim 1, said lens cover includes an undersurface partly comprising a spherical section.

11) Semiconductor light sources of claim 1, said substrate includes at least one fill port.

12) Semiconductor light sources of claim 11, said substrate includes an exit port.

13) Semiconductor light sources of claim 11, further comprises a deflector element affixed to said substrate adjacent and proximate to the filling port next to a semiconductor mounting pad.

14) Semiconductor light sources of claim 1, said optically cooperative material includes a combination of at least two distinct volumes; a first volume is arranged as wavelength shifting media and a second volume is arranged as a dispersant agent, the combination of distinct volumes fills and occupies the space of the cavity formed between the lens cover and the substrate.

15) Semiconductor light sources of claim 14, a semiconductor chip is first enveloped by a first optically cooperative material and thereafter by a second optically cooperative material.

16) Semiconductor light sources of claim 14, said substrate is further comprised of a plurality of semiconductor mounting pads and plurality of fill ports having a one-to-one correspondence with respect to the semiconductor mounting pads, each mounting pad having a semiconductor light emitter mounted thereto.

17) Semiconductor light sources of claim 16, said second volume is arranged into a plurality of discrete orbs each forming an association with a particular semiconductor light emitter as it completely surrounds and envelops either of the semiconductor light emitters.

18) Semiconductor light sources of claim 17, each orb is an optically cooperative material of different composition.

19) Semiconductor light sources of claim 1, said lens cover is further characterized as having an undersurface arranged to form two distinct axially symmetric, concentric cavities, said substrate having at least two fill ports, one each associated with and coupled to each cavity.

20) Semiconductor light sources of claim 19, a first centrally disposed cavity is filled with a first optically cooperative material, and a second annular cavity is filled with a second optically cooperative material.
